(19) United States
(12) Patent Application Publication
(10) Pub. No.: US 2026/0343927 A1
(43) Pub. Date: Oct. 29, 2026

(54) GROUP III ELEMENT NITRIDE SUBSTRATE, SEMICONDUCTOR DEVICE, METHOD OF PROCESSING A GROUP-III ELEMENT NITRIDE SUBSTRATE, AND METHOD OF PRODUCING A SEMICONDUCTOR DEVICE

(71) Applicant: NGK Corporation, Nagoya-shi (JP)

(72) Inventors: Yoshitaka KURAOKA, Okazaki-shi (JP); Shohei OUE, Nagoya-shi (JP); Ryozo KISHIMOTO, Iwakura-shi (JP)

(21) Appl. No.: 19/699,221

(22) Filed: Jun. 5, 2026

Related U.S. Application Data
(63) Continuation of application No. PCT/JP2023/044075, filed on Dec. 8, 2023.

(51) Int. Cl. H10D 30/47; H10D 62/85; H10P 58/00

(52) U.S. Cl. CPC H10D 30/471; H10D 62/8503; H10P 58/00

(57) ABSTRACT

The Group-III element nitride substrate is a Group-III element nitride substrate doped with a transition element, wherein the Group-III element nitride substrate has an absorption coefficient of light having a wavelength λ of 400 nm or more of 22 cm⁻¹ or more.

### CROSS-REFERENCE TO RELATED APPLICATIONS

This application is a continuation under 35 U.S.C. 120 of International Application PCT/JP2023/044075 having the International Filing Date of Dec. 8, 2023. The identified application is fully incorporated herein by reference.

### BACKGROUND OF THE INVENTION

### 1. Field of the Invention

The present disclosure relates to a Group-III element nitride substrate, a semiconductor device, a method of processing a Group-III element nitride substrate, and a method of producing a semiconductor device.

### 2. Description of the Related Art

A Group-III element nitride has a direct transition wide bandgap, a high dielectric breakdown field, and a high saturation electron speed, and hence has been actively developed as, for example, a semiconductor material for a high-frequency/high-power electronic device.

For example, as described in Patent Literature 1, the above-mentioned Group-III element nitride has been desired to have high resistance in some applications.

### CITATION LIST

### Patent Literature

[PTL 1] JP 5451085 B2

### SUMMARY OF THE INVENTION

The above-mentioned Group-III element nitride substrate cannot be easily subjected to a cutting process using a laser (e.g., operation of dividing the substrate into individual pieces) in some cases.

In view of the foregoing, a primary object of the present disclosure is to provide a Group-III element nitride substrate having excellent processability.

1. According to one embodiment of the present disclosure, there is provided a Group-III element nitride substrate doped with a transition element, wherein the Group-III element nitride substrate has an absorption coefficient of light having a wavelength λ of 400 nm or more of 22 cm⁻¹ or more.

2. The Group-III element nitride substrate according to the above-mentioned item 1 may have a concentration of oxygen of 7×10¹⁵ cm⁻³ or more.

3. The Group-III element nitride substrate according to the above-mentioned item 1 or 2 may have a concentration of manganese of 6×10¹⁷ cm⁻³ or more.

4. The Group-III element nitride substrate according to any one of the above-mentioned items 1 to 3 may have a concentration of oxygen of 8×10¹⁶ cm⁻³ or less.

5. The Group-III element nitride substrate according to any one of the above-mentioned items 1 to 4 may have a concentration of manganese of 1×10¹⁹ cm⁻³ or less.

6. In the Group-III element nitride substrate according to any one of the above-mentioned items 1 to 5, the wavelength λ may fall within a range of from 770 nm to 830 nm.

7. The Group-III element nitride substrate according to any one of the above-mentioned items 1 to 6 may contain gallium nitride.

8. The Group-III element nitride substrate according to any one of the above-mentioned items 1 to 7 may have a resistivity determined by measuring a time-dependent change in charge amount of 1×10⁵Ω·cm or more.

9. The Group-III element nitride substrate according to any one of the above-mentioned items 1 to 8 may have a dislocation density of 1×10⁷ cm⁻² or less.

10. According to another embodiment of the present disclosure, there is provided a semiconductor device, including: a laminated structure including the Group-III element nitride substrate of any one of the above-mentioned items 1 to 9, a channel layer, and a barrier layer in this order; and a source electrode, a drain electrode, and a gate electrode arranged on the laminated structure.

11. According to another embodiment of the present disclosure, there is provided a method of processing a Group-III element nitride substrate, the method including: temporarily fixing the Group-III element nitride substrate of any one of the above-mentioned items 1 to 9 to a sheet for processing; and irradiating the Group-III element nitride substrate with laser light having a wavelength of 400 nm or more along a preset dividing line under a state in which the Group-III element nitride substrate is temporarily fixed to the sheet for processing.

12. In the method of processing a Group-III element nitride substrate according to the above-mentioned item 11, the sheet for processing may be reduced in pressure-sensitive adhesive strength by irradiation with light having a wavelength of less than 400 nm.

13. According to another embodiment of the present disclosure, there is provided a method of producing a semiconductor device, the method including: forming a channel layer and a barrier layer on the Group-III element nitride substrate of any one of the above-mentioned items 1 to 9 to provide a laminated structure; arranging a source electrode, a drain electrode, and a gate electrode on the laminated structure; temporarily fixing the Group-III element nitride substrate to a sheet for processing; and irradiating the Group-III element nitride substrate with laser light having a wavelength of 400 nm or more along a preset dividing line under a state in which the Group-III element nitride substrate is temporarily fixed to the sheet for processing.

14. In the method of producing a semiconductor device according to the above-mentioned item 13, the laminated structure may be obtained by epitaxial growth.

15. In the method of producing a semiconductor device according to the above-mentioned item 13 or 14, the sheet for processing may be reduced in pressure-sensitive adhesive strength by irradiation with light having a wavelength of less than 400 nm.

According to the embodiments of the present disclosure, the Group-III element nitride substrate having excellent processability can be provided.

### BRIEF DESCRIPTION OF THE DRAWINGS

FIG. 1 is a schematic sectional view for illustrating the schematic configuration of a Group-III element nitride substrate according to one embodiment of the present disclosure.

FIG. 2 is a plan view of the Group-III element nitride substrate illustrated in FIG. 1.

FIG. 3A is a view for illustrating a production process for a Group-III element nitride substrate according to one embodiment.

FIG. 3B is a view subsequent to FIG. 3A.

FIG. 3C is a view subsequent to FIG. 3B.

FIG. 4 is a schematic sectional view for illustrating the schematic configuration of a semiconductor device according to one embodiment of the present disclosure.

FIG. 5A is a sectional view for schematically illustrating a method of processing a Group-III element nitride substrate according to one embodiment.

FIG. 5B is a view subsequent to FIG. 5A.

FIG. 6 shows a light transmittance measurement result of a gallium nitride substrate of Sample 5 in Experimental Example 1.

### DESCRIPTION OF THE EMBODIMENTS

Embodiments of the present disclosure are described below with reference to the drawings, but the present disclosure is not limited to these embodiments. For clearer illustration, some widths, thicknesses, shapes, and the like of respective portions may be schematically illustrated in the drawings in comparison to the embodiments. However, the widths, the thicknesses, the shapes, and the like are each merely an example, and do not limit the interpretation of the present disclosure. In addition, in the drawings, the same or similar components are denoted by the same reference symbols, and repetitive description thereof may be omitted.

### A. Group-III Element Nitride Substrate

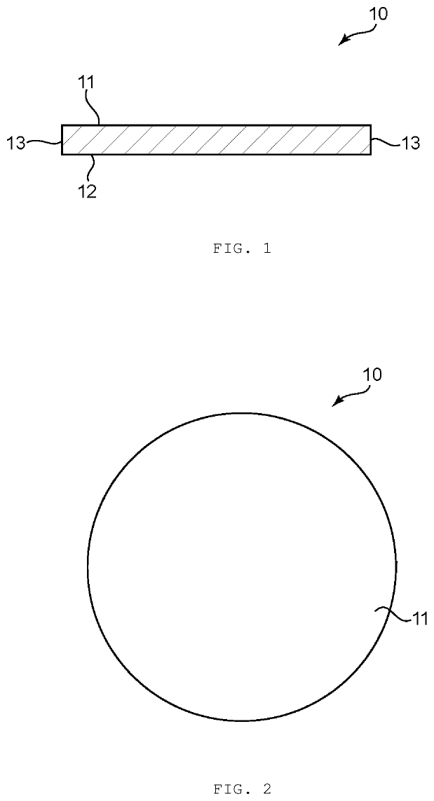

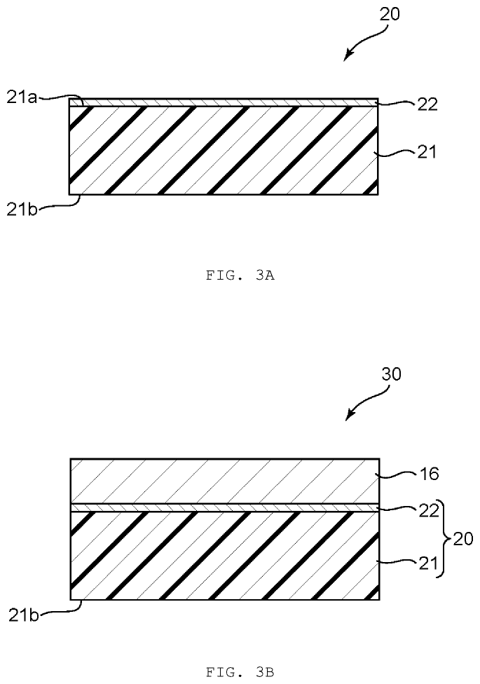

FIG. 1 is a schematic sectional view for illustrating the schematic configuration of a Group-III element nitride substrate according to one embodiment of the present disclosure. FIG. 2 is a plan view of the Group-III element nitride substrate illustrated in FIG. 1. A Group-III element nitride substrate 10 has a plate shape and includes a first main surface 11 and a second main surface 12 facing each other. The main surfaces are linked to each other via a side surface 13.

In the illustrated examples, the Group-III element nitride substrate has a disc shape (wafer), but the shape is not limited thereto and any appropriate shape may be adopted. The size of the Group-III element nitride substrate may be appropriately set in accordance with purposes. The diameter of the Group-III element nitride substrate having a disc shape is, for example, 50 mm or more and 200 mm or less. The thickness of the Group-III element nitride substrate is, for example, 250 μm or more and 800 μm or less.

In one embodiment, the resistivity of the Group-III element nitride substrate is, for example, 1×10⁵Ω·cm or more and 1×10¹⁴Ω·cm or less, preferably 1×10⁶Ω·cm or more, more preferably 1×10⁷Ω·cm or more. Such semi-insulating Group-III element nitride substrate may be suitably used as, for example, a substrate for a high-electron-mobility transistor (HEMT) device. Specifically, a channel layer and a barrier layer are formed on the Group-III element nitride substrate, and the resultant may be used as the HEMT device.

The resistivity of the above-mentioned Group-III element nitride substrate may be determined by measuring a time-dependent change in charge amount. The resistivity can be determined by measuring the time-dependent change in charge amount without breakage of the Group-III element nitride substrate. Specifically, the Group-III element nitride substrate is inserted into a capacitor including a probe and a stage, and a pulse voltage is applied thereto. In this state, the time-dependent change in charge amount of the Group-III element nitride substrate is measured, and the resistivity is calculated from the measured value. In this case, the probe is not brought into contact with the Group-III element nitride substrate, and hence the resistivity can be determined without formation of an ohmic contact electrode. The spatial resolution of the probe may be from about 1 mm to about 10 mm. A method of determining the resistivity is described in, for example, the non-patent literature “R. Stibal et al., “Contactless evaluation of semi-insulating GaAs wafer resistivity using the time-dependent charge measurement,” Semiconductor Science and Technology, 6, p. 995 (1991).”

In one embodiment, the Group-III element nitride substrate can absorb light having a wavelength of 400 nm or more. Specifically, the Group-III element nitride substrate has an absorption coefficient of light having a wavelength λ of 400 nm or more of, for example, 22 cm⁻¹ or more, preferably 25 cm⁻¹ or more. When the Group-III element nitride substrate has such light absorption characteristic, the processing of the substrate using laser light having a wavelength of 400 nm or more can be achieved. Typically, the division of the substrate can be achieved using laser light having a wavelength of 400 nm or more. Meanwhile, the absorption coefficient of the light having the wavelength λ of 400 nm or more of the Group-III element nitride substrate is, for example, 35 cm⁻¹ or less, and may be 30 cm⁻¹ or less.

The above-mentioned wavelength λ of 400 nm or more is preferably 700 nm or more, and may be, for example, about 800 nm. Specifically, the wavelength λ of 400 nm or more may fall within the range of from 770 nm to 830 nm. In this case, the wavelength λ may be a wavelength at which the substrate shows the lowest light transmittance in the range of from 770 nm to 830 nm. The Group-III element nitride substrate may show a high absorptance for light having a wavelength equal to or less than wavelength corresponding to the bandgap energy of the substrate. For example, a gallium nitride substrate may show a high absorptance for light having a wavelength of 365 nm or less.

The dislocation density of the Group-III element nitride substrate evaluated by a cathodoluminescence method is, for example, 1×10⁸ cm⁻² or less, preferably 5×10⁷ cm⁻² or less, more preferably 1×10⁷ cm⁻² or less, still more preferably 6×10⁶ cm⁻² or less, particularly preferably 2×10⁶ cm⁻² or less. Meanwhile, the dislocation density of the Group-III element nitride substrate evaluated by the cathodoluminescence method may be, for example, 1×10⁴ cm⁻² or more.

The Group-III element nitride substrate includes a Group-III element nitride crystal. For example, aluminum (Al), gallium (Ga), or indium (In) is used as a Group-III element for forming a Group-III element nitride. Those elements may be used alone or in combination thereof. Specific examples of the Group-III element nitride include aluminum nitride (AlₓN), gallium nitride (Ga_{y}N), indium nitride (In_{z}N), aluminum gallium nitride (AlₓGa_{y}N), gallium indium nitride (Ga_{y}In_{z}N), aluminum indium nitride (AlₓIn_{z}N), and aluminum gallium indium nitride (AlₓGa_{y}In_{z}N). In each of the chemical formulae in parentheses, typically, x+y+z=1 is satisfied.

The above-mentioned Group-III element nitride is doped with an element except a Group-III element. Specifically, the Group-III element nitride contains an element except a Group-III element as a dopant. When the Group-III element nitride is doped with an element except a Group-III element, a Group-III element nitride substrate (semi-insulating Group-III element nitride substrate) that can fully satisfy the above-mentioned resistivity can be obtained. A transition element, such as iron (Fe), manganese (Mn), vanadium (V), chromium (Cr), cobalt (Co), or nickel (Ni), is preferably used as the above-mentioned dopant. Those elements may be used alone or in combination thereof. Of those, manganese is preferably used as the dopant.

The Group-III element nitride substrate may contain manganese. When manganese is incorporated, a Group-III element nitride substrate that can fully satisfy the above-mentioned light absorption characteristic can be obtained. The abundance (unit: atoms/cm³) of manganese in the Group-III element nitride substrate may be set to any appropriate value. The abundance (unit: atoms/cm³) of manganese in the Group-III element nitride substrate is hereinafter sometimes simply referred to as “manganese concentration” (unit: cm⁻³). The manganese concentration is, for example, 6×10¹⁷ cm⁻³ or more, preferably 7×10¹⁷ cm⁻³ or more, more preferably 8×10¹⁷ cm⁻³ or more, still more preferably 9×10¹⁷ cm⁻³ or more, particularly preferably 1×10¹⁸ cm⁻³ or more.

The manganese concentration is, for example, 1×10²⁰ cm⁻³ or less, preferably 5×10¹⁹ cm⁻³ or less, more preferably 3×10¹⁹ cm⁻³ or less, still more preferably 1×10¹⁹ cm⁻³ or less. According to such manganese concentration, for example, the Group-III element nitride substrate that can fully satisfy the above-mentioned resistivity and/or dislocation density can be obtained.

The Group-III element nitride substrate may contain oxygen. When oxygen is incorporated, a Group-III element nitride substrate that can fully satisfy the above-mentioned light absorption characteristic can be obtained. The abundance (unit: atoms/cm³) of oxygen in the Group-III element nitride substrate may be set to any appropriate value. The abundance (unit: atoms/cm³) of oxygen in the Group-III element nitride substrate is hereinafter sometimes simply referred to as “oxygen concentration” (unit: cm⁻³). The oxygen concentration is, for example, 6×10¹⁵ cm⁻³ or more, and may be 7×10¹⁵ cm⁻³ or more, may be 8×10¹⁵ cm⁻³ or more, may be 9×10¹⁵ cm⁻³ or more, may be 1×10¹⁶ cm⁻³ or more, or may be 2×10¹⁶ cm⁻³ or more.

The oxygen concentration is, for example, 1×10¹⁸ cm⁻³ or less, preferably 3×10¹⁷ cm⁻³ or less, more preferably 1×10¹⁷ cm-3 or less, still more preferably 8×10¹⁶ cm⁻³ or less.

In the above-mentioned Group-III element nitride crystal, typically, the <0001> direction is the c-axis direction, the <1-100> direction is the m-axis direction, and the <11-20> direction is the a-axis direction. In addition, the crystal plane perpendicular to the c-axis is the c-plane, the crystal plane perpendicular to the m-axis is the m-plane, and the crystal plane perpendicular to the a-axis is the a-plane. In one embodiment, the thickness direction of the Group-III element nitride substrate is parallel or approximately parallel to the c-axis, and the first main surface 11 is a Group-III element polar surface on a (0001) plane side, and the second main surface 12 is a nitrogen polar surface on a (000-1) plane side. The first main surface 11 may be parallel to the (0001) plane, or may be tilted with respect to the (0001) plane. The angle of the tilt of the first main surface 11 with respect to the (0001) plane is, for example, 10° or less, and may be 5° or less, may be 2° or less, or may be 1° or less. The second main surface 12 may be parallel to the (000-1) plane, or may be tilted with respect to the (000-1) plane. The angle of the tilt of the second main surface 12 with respect to the (000-1) plane is, for example, 10° or less, and may be 5° or less, may be 2° or less, or may be 1° or less.

### B. Production Method

A method of producing a Group-III element nitride substrate according to one embodiment of the present disclosure includes: preparing a seed crystal substrate including a base substrate and a seed crystal film; and growing a Group-III element nitride crystal doped with an element except a Group-III element on the seed crystal film of the seed crystal substrate.

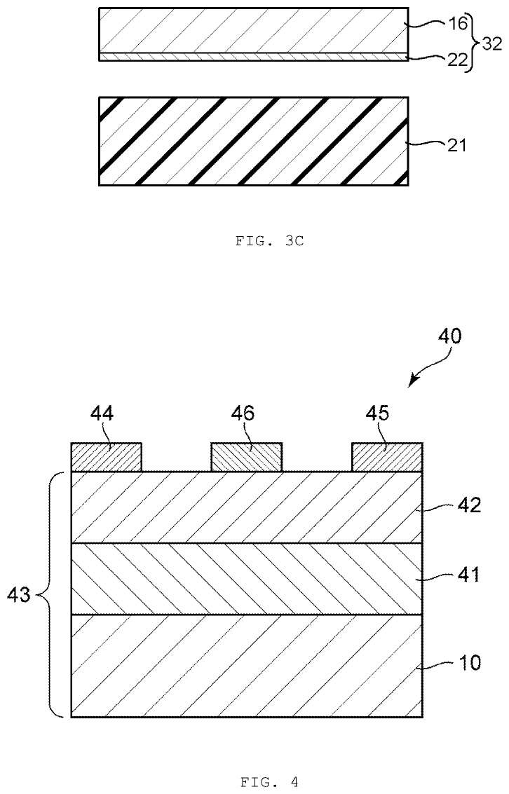

FIG. 3A to FIG. 3C are each a view for illustrating a production process for a Group-III element nitride substrate according to one embodiment. In FIG. 3A, there is illustrated a state in which a seed crystal film 22 has been formed on an upper surface 21a of a base substrate 21 including the upper surface 21a and a lower surface 21b facing each other to complete a seed crystal substrate 20.

For example, a substrate having such a shape and size that a Group-III element nitride substrate having a desired shape and size can be produced is used as the above-mentioned base substrate. Typically, the base substrate is formed into a disc shape having a diameter of from 50 mm to 200 mm. The thickness of the base substrate is, for example, from 200 μm to 800 μm.

Any appropriate substrate may be used as the base substrate. Typically, the base substrate includes a monocrystalline body. A material for forming the base substrate is, for example, sapphire, crystal-oriented alumina, silicon, gallium oxide, aluminum gallium nitride, gallium arsenide, or silicon carbide (Sic).

The thickness of the above-mentioned seed crystal film is, for example, 0.2 μm or more. From the viewpoint of preventing the meltback and disappearance of the Group-III element nitride crystal during its growth, the thickness of the seed crystal film is preferably 1 μm or more, more preferably 2 μm or more. Meanwhile, from the viewpoint of productivity, the thickness of the seed crystal film is preferably 10 μm or less, more preferably 5 μm or less.

Any appropriate material may be adopted as a material for forming the seed crystal film. A Group-III element nitride is typically used as the material for forming the seed crystal film. Details about the Group-III element nitride are as described above.

The seed crystal film may be formed by any appropriate method. A vapor phase epitaxy method is typically used as a method of forming the seed crystal film. Specific examples of the vapor phase epitaxy method include a metal-organic chemical vapor deposition (MOCVD) method, a hydride vapor phase epitaxy (HVPE) method, a pulsed excitation deposition (PXD) method, a molecular-beam epitaxy (MBE) method, a vapor deposition method, and a sublimation method. Of those, an MOCVD method is preferably used.

The formation of the seed crystal film by the above-mentioned MOCVD method includes, for example, a first formation step and a second formation step in this order. Specifically, the first formation step includes a first forming layer (low-temperature grown buffer layer) (not shown) on the base substrate at a temperature T1 (e.g., from 450 °C to 550 °C), and the second formation step includes forming a second layer (not shown) at a temperature T2 (e.g., from 1,000 °C to 1,200 °C) higher than the temperature T1. The thickness of the first layer is, for example, from 20 nm to 50 nm. The thickness of the second layer is, for example, from 1 μm to 5 μm.

Next, a Group-III element nitride crystal is grown on the seed crystal film 22 of the seed crystal substrate 20 to form a Group-III element nitride crystal layer 16. Thus, a laminated substrate 30 is obtained as illustrated in FIG. 3B. The degree of growth of the Group-III element nitride crystal (thickness of the Group-III element nitride crystal layer 16) may be adjusted in accordance with a desired thickness of the Group-III element nitride substrate. Any appropriate direction may be selected as the growth direction of the Group-III element nitride crystal in accordance with, for example, applications or purposes. Specific examples thereof include: the normal direction of each of the above-mentioned c-plane, a-plane, and m-plane; and the normal direction of a plane tilted with respect to each of the above-mentioned c-plane, a-plane, and m-plane.

The Group-III element nitride crystal may be grown by any appropriate method. The method of growing the Group-III element nitride crystal is not particularly limited as long as a crystal direction substantially following the crystal direction of the above-mentioned seed crystal film can be achieved by the method. Specific examples of the method of growing the Group-III element nitride crystal include: vapor phase epitaxy methods, such as a metal-organic chemical vapor deposition (MOCVD) method, a hydride vapor phase epitaxy (HVPE) method, a pulsed excitation deposition (PXD) method, a molecular-beam epitaxy (MBE) method, and a sublimation method; and liquid phase epitaxy methods, such as a flux method, an ammonothermal method, a hydrothermal method, and a sol-gel method. Those methods may be used alone or in combination thereof.

The flux method (e.g., a Na flux method) is preferably adopted as the method of growing the Group-III element nitride crystal. Details about such growth method are described in, for example, JP 5451085 B2, and the growth may be performed by appropriately adjusting the various conditions of the described growth method. Specifically, the growth of the Group-III element nitride crystal may be performed by adjusting various conditions with a crystal-producing apparatus including: a pressure-resistant vessel to which a high-pressure nitrogen gas can be supplied; a rotary table rotatable within the pressure-resistant vessel; and an outer vessel to be mounted on the rotary table.

The growth of the Group-III element nitride crystal by the flux method is typically performed with a crucible serving as a growth vessel. Specifically, the above-mentioned seed crystal substrate is placed at a predetermined position in the crucible, and further, raw materials are loaded into the crucible. The crucible in which the seed crystal substrate is placed is typically, in a state of being closed with a lid, placed at predetermined pressure and temperature under an atmosphere containing nitrogen, and subjected to a growth process.

The above-mentioned raw materials are, for example, a melt composition containing flux, a Group-III element, and a dopant. The flux preferably contains at least one of an alkali metal or an alkaline earth metal, and more preferably contains metal sodium. Typically, the flux and a metal raw material substance are used as a mixture thereof. An elemental metal, an alloy, a metal compound, or the like may be used as the metal raw material substance, but the elemental metal is preferably used from the viewpoint of handling.

The above-mentioned crucible (including a lid) may be formed of any appropriate material that may be used in the flux method. Examples of the material for the crucible include alumina, yttria, and yttrium aluminum garnet (YAG). In addition, the material for the crucible may be a single crystal or a polycrystal (ceramic). The ceramic may be a ceramic with so-called translucency having a relative density increased by HIP treatment or the like.

The growth may be performed under the atmosphere containing nitrogen as described above. The growth atmosphere may contain other gases in addition to nitrogen. Inert gases, such as argon, helium, and neon, are preferably used as the other gases.

The pressure of the atmosphere during the growth may be set to any appropriate pressure. The pressure of the atmosphere during the growth is, for example, 1 MPa or more, and may be 2 MPa or more, or may be 3 MPa or more from the viewpoint of, for example, preventing the evaporation of the flux. Meanwhile, the pressure of the atmosphere during the growth is, for example, 50 MPa or less, and may be 10 MPa or less from the viewpoint of, for example, preventing a growing apparatus from becoming too large.

The temperature of the atmosphere during the growth may be set to any appropriate temperature. The temperature of the atmosphere during the growth is preferably from 700 °C to 1,000 °C, more preferably from 800 °C to 900 °C. In one embodiment, the above-mentioned desired oxygen concentration can be achieved by adjusting the temperature of the atmosphere during the growth.

The growth is preferably performed while the base substrate (crucible) is rotated from the viewpoint of, for example, promoting the dissolution of a high-pressure nitrogen gas into the above-mentioned melt composition. For example, the crucible closed with a lid is accommodated in the outer vessel of the above-mentioned crystal-producing apparatus and mounted on the rotary table, and the crucible is rotated by rotating (e.g., axial rotating) the rotary table in this state.

After the growth of the Group-III element nitride crystal, as illustrated in FIG. 3C, a freestanding substrate 32 is obtained by removing the base substrate 21 from the Group-III element nitride crystal (Group-III element nitride crystal layer 16). Typically, as illustrated in FIG. 3C, the freestanding substrate 32 may include the Group-III element nitride crystal layer 16 and the seed crystal film 22. For example, the freestanding substrate 32 is obtained by separating the Group-III element nitride crystal layer 16 from the base substrate 21. The Group-III element nitride crystal may be separated from the base substrate by any appropriate method. Examples of the method of separating the Group-III element nitride crystal include: a method of causing spontaneous separation the base substrate by utilizing a thermal shrinkage difference between the Group-III element nitride crystal and the base substrate in a temperature decrease step after the growth of the Group-III element nitride crystal; a separation method including chemical etching; and a laser lift-off method including laser light irradiation. In addition, for example, the freestanding substrate may be obtained by a method of removing the base substrate 21 by grinding, or a method including slicing with a wire saw or the like.

The freestanding substrate 32 may be used as it is for the above-mentioned Group-III element nitride substrate. However, typically, the freestanding substrate 32 is subjected to any appropriate processing to provide the above-mentioned Group-III element nitride substrate.

An example of the processing to which the above-mentioned freestanding substrate is subjected is grinding (e.g., grinding with a diamond grinding wheel) of its peripheral edge portion. Typically, the freestanding substrate is processed into the above-mentioned desired shape and size (e.g., a disc shape having a desired diameter) by grinding.

Another example of the processing to which the above-mentioned freestanding substrate is subjected is processing, such as grinding or polishing (e.g., lap polishing or chemical-mechanical polishing (CMP)), of its main surfaces (upper surface and lower surface). Typically, the freestanding substrate is thinned and flattened by the grinding and the polishing so as to have a desired thickness. In one embodiment, the freestanding substrate may be brought into a state of the Group-III element nitride crystal layer 16 alone (a single crystal growth layer alone) by removing the seed crystal film 22 through the processing of the main surface.

In addition, examples of the processing to which the above-mentioned freestanding substrate is subjected include chamfering of its outer peripheral edge, removal of an affected layer formed on the surface by grinding or polishing, and removal of a residual stress that may result from the affected layer.

### C. Applications

The above-mentioned Group-III element nitride substrate is typically applicable to any appropriate semiconductor device. Specifically, any appropriate upper structure layer may be formed on the Group-III element nitride substrate.

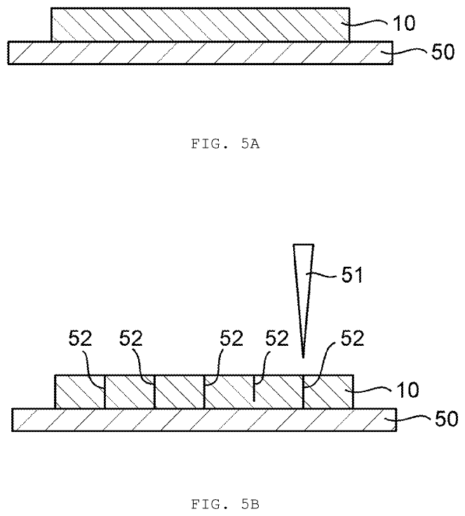

FIG. 4 is a schematic sectional view for illustrating the schematic configuration of a semiconductor device according to one embodiment of the present disclosure by using a HEMT device as an example. A HEMT device 40 includes: a laminated structure 43 including the Group-III element nitride substrate 10, a channel layer 41, and a barrier layer 42 in this order; and a source electrode 44, a drain electrode 45, and a gate electrode 46 arranged on the laminated structure 43. Those electrodes may each be a metal electrode having a thickness of from about a little over ten nanometers to about a hundred and several tens of nanometers.

The laminated structure 43 may be obtained by heterogeneous growth of the respective layers. For example, the channel layer 41 and the barrier layer 42 may be formed above the Group-III element nitride substrate 10 by epitaxial growth. The thickness of the channel layer 41 is, for example, from 50 nm to 5 μm. The thickness of the barrier layer 42 is, for example, from 2 nm to 40 nm.

The Group-III element nitride crystal may be adopted as each of materials for forming the channel layer 41 and the barrier layer 42. For example, gallium (Ga), aluminum (Al), or indium (In) is used as a Group-III element for forming a Group-III element nitride. Those elements may be used alone or in combination thereof. In one embodiment, the Group-III element nitride substrate 10 may include gallium nitride doped with an element except Ga. In this case, the channel layer 41 preferably includes gallium nitride. In addition, the barrier layer 42 preferably includes at least one selected from aluminum gallium nitride, aluminum indium nitride, and aluminum indium gallium nitride.

The channel layer 41 and the barrier layer 42 may each be formed by any appropriate method. In one embodiment, the channel layer 41 and the barrier layer 42 may each be formed by an MOCVD method. When the channel layer 41 and the barrier layer 42 are each formed by the MOCVD method, a metal-organic (MO) raw material gas may be used as a Group-III element source. For example, when a gallium nitride layer and an aluminum gallium nitride layer are formed as the channel layer 41 and the barrier layer 42, respectively, by the MOCVD method, trimethyl gallium (TMG) and trimethyl aluminum (TMA) may be used as a Ga source and an Al source, respectively. In addition, an ammonia gas may be used as a nitrogen source. In addition, at least one of a hydrogen gas or a nitrogen gas may be used as a carrier gas.

Although not shown, a buffer layer may be arranged between the Group-III element nitride substrate 10 and the channel layer 41. For example, the buffer layer may be formed at the time of the formation of the channel layer and may include materials for forming the channel layer.

The above-mentioned Group-III element nitride substrate may be divided and singulated. Specifically, the Group-III element nitride substrate may be divided before or after the formation of an upper structure layer including various layers, such as an epitaxial growth layer, a passivation film, and an electrode, thereon, or in the middle of the formation of the upper structure layer thereon.

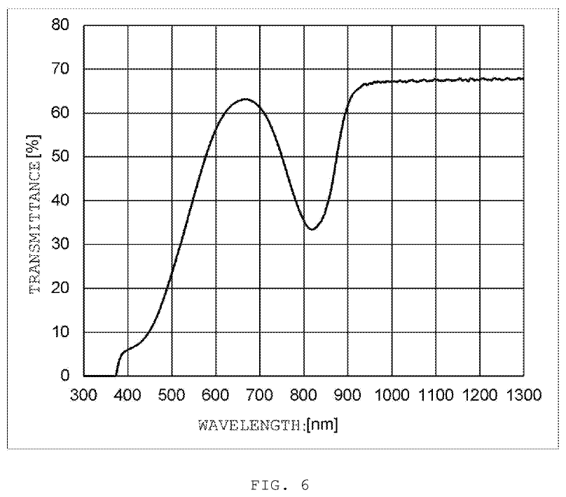

FIG. 5A and FIG. 5B are each a sectional view for schematically illustrating a method of processing a Group-III element nitride substrate according to one embodiment. In each of FIG. 5A and FIG. 5B, the upper structure layer that may be formed on the Group-III element nitride substrate is omitted.

A state in which the Group-III element nitride substrate 10 is temporarily fixed to a sheet 50 for processing is illustrated in FIG. 5A. Typically, a sheet (e.g., a dicing tape) that may be reduced in pressure-sensitive adhesive strength by irradiation with light is used as the sheet 50 for processing. After that, as illustrated in FIG. 5B, the Group-III element nitride substrate 10 is irradiated with laser light 51 under a state in which the Group-III element nitride substrate 10 is temporarily fixed to the sheet 50 for processing. A processing groove 52 may be formed in the Group-III element nitride substrate 10 by the irradiation with the laser light 51. According to the laser irradiation, the processing groove may be formed while the generation of dust due to processing is suppressed.

The wavelength of the laser light 51 is preferably 400 nm or more, more preferably 700 nm or more. For example, the laser light 51 may be visible laser light and/or infrared laser light. When the Group-III element nitride substrate 10 temporarily fixed to the sheet 50 for processing is irradiated with light having a wavelength of less than 400 nm (e.g., ultraviolet light having a wavelength of 200 nm or more and less than 400 nm), the sheet 50 for processing may be reduced in pressure-sensitive adhesive strength. For example, the pressure-sensitive adhesive layer (not shown) of the sheet 50 for processing may be cured by the irradiation with the light having a wavelength of less than 400 nm, and hence the sheet may be reduced in pressure-sensitive adhesive strength. Specifically, the sheet 50 for processing may be reduced in pressure-sensitive adhesive strength at the application point of the light having a wavelength of less than 400 nm and at a peripheral portion that may be affected by scattered light thereof. Owing to the reduction in pressure-sensitive adhesive strength of the sheet 50 for processing, for example, there is a risk in that processing accuracy is reduced because the Group-III element nitride substrate 10 lifts up from the sheet 50 for processing, or processability is reduced because the Group-III element nitride substrate 10 peels off from the sheet 50 for processing during processing. As described above, the Group-III element nitride substrate 10 can absorb light having a wavelength of 400 nm or more, and hence, when the wavelength of the laser light 51 is set to 400 nm or more, the processing of the Group-III element nitride substrate 10 can be satisfactorily performed without any reduction in pressure-sensitive adhesive strength of the sheet 50 for processing even under a state in which the substrate is temporarily fixed to the sheet 50 for processing. In addition, the use of the Group-III element nitride substrate 10 can contribute to an improvement in yield.

A light source (laser for processing) for the laser light having a wavelength of 400 nm or more is, for example, a titanium sapphire (Ti:Al₂O₃) laser, a diode pumped solid state (DPSS) laser using a semiconductor laser as excitation light, or an erbium-doped fiber laser.

Typically, the laser light 51 may be applied along a preset dividing line. In the illustrated example, the laser light 51 is applied from a side closer to the Group-III element nitride substrate 10 (upper side in FIG. 5B), but may be applied from a side closer to the sheet 50 for processing (lower side in FIG. 5B). Application conditions for the laser light 51 may be set to any appropriate conditions. In one embodiment, the processing groove 52 of the Group-III element nitride substrate 10 formed by the laser irradiation may penetrate the Group-III element nitride substrate 10. Specifically, when a cleavage plane (crystal plane) for highly accurate alignment (e.g., alignment during the formation of an electrode) is not required for an individual piece obtained by dividing the Group-III element nitride substrate, the Group-III element nitride substrate does not have to be cleaved along the processing groove. For example, when a semiconductor device for high frequency applications is produced, the Group-III element nitride substrate does not have to be cleaved along the processing groove.

### EXAMPLES

The present disclosure is specifically described below by way of Examples, but the present disclosure is not limited to these Examples.

### Experimental Example 1

### (Production of Seed Crystal Substrates)

A plurality of c-plane sapphire substrates each having a diameter of 4 inches were prepared. A gallium nitride film having a thickness of 2 μm was formed on the respective sapphire substrates by an MOCVD method to produce seed crystal substrates.

### (Growth of Gallium Nitride Crystals)

The growth of a gallium nitride crystal on each of the seed crystal substrates was performed with a crystal-producing apparatus including: a pressure-resistant vessel to which a high-pressure nitrogen gas was able to be supplied; a rotary table rotatable in the pressure-resistant vessel; an outer vessel to be mounted on the rotary table; and a crystal growth furnace for placing the outer vessel under a desired temperature environment.

The resultant seed crystal substrates were placed in each alumina crucible in a glove box under a nitrogen atmosphere. Next, 40 g of metal gallium, 80 g of metal sodium, and 0.01 g to 0.10 g of manganese serving as a doping element were each melted in the glove box and loaded into each crucible. The seed crystal substrates were immersed in each flux melt, followed by the covering of the crucibles with alumina plates. In this state, the crucibles were loaded into stainless steel-made inner vessels, and the inner vessels were further loaded into a stainless steel-made outer vessel capable of accommodating the inner vessels, followed by the closing of the outer vessel with a lid provided with a nitrogen-introducing pipe. In this state, the outer vessel was mounted on the rotary table arranged in the crystal-producing apparatus, and the pressure-resistant vessel of the crystal-producing apparatus was closed with a lid and hermetically sealed.

Subsequently, while a heater portion was operated to heat the crystal growth furnace in the crystal-producing apparatus so that its temperature uniformly became 850 °C, a nitrogen gas was introduced into the pressure-resistant vessel from nitrogen gas cylinders until a pressure therein became 4 MPa, and the outer vessel was horizontally rotated. This state was held for 35 hours to grow a gallium nitride crystal on each of the seed crystal substrates.

After that, the vessel was naturally cooled to room temperature and reduced in pressure to atmospheric pressure, and then the lid of the alumina crucible was opened. As a result, the following state was established: the grown gallium nitride crystal and the sapphire substrate were spontaneously separated from each other. Thus, gallium nitride crystals each having a diameter of 4 inches and a thickness of 1 mm were obtained.

After that, in each of the resultant gallium nitride crystals, the surface peeled from the sapphire substrate and the opposite surface were flattened by polishing with diamond abrasive grains. Thus, Mn-doped gallium nitride substrates each having a diameter of 4 inches and a thickness of 0.43 mm were obtained.

### Experimental Example 2

Mn-doped gallium nitride substrates were obtained in the same manner as in Experimental Example 1 except that the set temperature of the crystal growth furnace was changed from 850 °C to the range of from 820 °C to 900 °C.

### <Evaluations>

The gallium nitride substrates obtained in Experimental Example 1 and Experimental Example 2 were subjected to the following evaluations. The evaluation results of the gallium nitride substrates obtained in Experimental Example 1 are shown in Table 1, and the evaluation results of the gallium nitride substrates obtained in Experimental Example 2 are shown in Table 2 together with the evaluation results of the gallium nitride substrates obtained in Experimental Example 1. In addition, as a representative, the measurement result of the light transmittance of the gallium nitride substrate of Sample 5 in Experimental Example 1 is shown in FIG. 6. Samples 1 to 10 in Table 1 differ from each other in loading amount of manganese in the growth of the gallium nitride crystal.

### 1. Laser Processing Test

A dicing tape was bonded to the lower side of the resultant substrate, and laser light was applied to the substrate from the upper side of the substrate. The laser light was applied so as to provide a chip having a size of 20 mm×20 mm from the substrate.

The laser irradiation was performed by using a titanium sapphire (Ti:Al₂O₃) laser (center wavelength: 820 nm) under the condition of an irradiation fluence of 0.5 J/cm².

The pressure-sensitive adhesive strength of the dicing tape was not changed by the laser irradiation, and the substrate was fixed to the dicing tape even after the laser irradiation.

### (Criteria)

Satisfactory: The substrate was cut by the laser irradiation.

Somewhat satisfactory: A processing groove was formed by the laser irradiation, but separation (singulation) into a chip was not able to be performed.

Poor: Substantial formation of a processing groove by the laser irradiation was not able to be observed.

### 2. Manganese Concentration and Oxygen Concentration

A measurement sample having a size of 20 mm×20 mm was cut out from the resultant substrate, and the manganese concentration and oxygen concentration thereof were determined by secondary ion mass spectrometry (SIMS). Measurement conditions are as described below.

### (Measurement Conditions)

Type of secondary ion mass spectrometer: Magnetic sector type
Element of primary ion: 02+ (for manganese measurement), Cs⁺ (for oxygen measurement)
Measurement range: From the surface to a depth of 5 μm
Information depth: Average value from a depth of 1 μm to a depth of 5 μm from the surface
Detection lower limit: 4×10¹⁴ cm⁻³ (for manganese measurement), 7×10¹⁵ cm⁻³ (for oxygen measurement)

### 3. Light Absorption Characteristic

The light absorption characteristic of the resultant substrate was evaluated. Specifically, a measurement sample having a size of 20 mm×20 mm was cut out from the resultant substrate, and its light transmittance was measured at room temperature with an ultraviolet-visible-near infrared spectrophotometer (“UH4150” manufactured by Hitachi High-Tech Science Corporation). Measurement conditions are as described below.

### (Measurement Conditions)

Start wavelength: 300 nm
End wavelength: 1,300 nm
Sampling interval: 2 nm
Scan speed: 300 nm/min
Slit width (resolution): 1 nm

An absorption coefficient α (unit: cm⁻¹) at a peak wavelength around 820 nm (from 815 nm to 825 nm) was determined from the resultant measurement data on the light transmittance by the following equation.

I=I₀×exp(−αt)
(I₀: intensity of incident light, I: intensity of transmitted light, “t”: thickness of measurement sample)

### 4. Resistivity

A resistivity within a substrate surface was measured by a non-contact method using a time-dependent change in charge amount. Specifically, the substrate was mounted on a stage, and a probe was brought close to the substrate (at a gap of from 1 mm to 2 mm) to configure a capacitor. A pulse voltage having a pulse width of 100 ns was applied, and the time-dependent change in charge amount of the substrate was measured at room temperature (25 °C) for 1 second, followed by the calculation of the resistivity. The magnitude of the resistivity was classified according to the following criteria.

### (Criteria)

A: The resistivity is 1×10⁷Ω·cm or more.
B: The resistivity is 1×10⁵Ω·cm or more and less than 1×10⁷Ω·cm.
C: The resistivity is less than 1×10⁵Ω·cm.

### 5. Dislocation Density

The dislocation density of the resultant semi-insulating (high resistance) gallium nitride substrate was determined by acquiring a cathodoluminescence (CL) image. Here, the acquisition of the CL image was performed by epitaxially growing a Si-doped GaN layer (thickness: 2 μm) that was able to have a dislocation density equivalent to that of the semi-insulating substrate on the gallium nitride substrate, and capturing the CL image of an epitaxial growth layer from the viewpoint of enhancing the emission of the CL image. Specifically, the CL image was acquired as a monochrome image by using a photomultiplier tube (PMT) as a detector under the conditions of an acceleration voltage of 15 kV and an emission current of 100 μA with a scanning electron microscope (“S-3400N” manufactured by Hitachi High-Technologies Corporation). Then, the dislocation density was calculated by counting dark spots in a predetermined region of the acquired image.

TABLE 1

| | | Mn | O | Absorption | Peak | | Dislocation |
|---|---|---|---|---|---|---|---|
| | Processing | concentration | concentration | coefficient | wavelength | | density |
| Sample | test | cm⁻³ | cm⁻³ | cm⁻¹ | nm | Resistivity | cm⁻² |
| 1 | Poor | 3 × 10¹⁷ | 6 × 10¹⁶ | 18.6 | 815 | C | 8.0 × 10⁵ |
| 2 | Poor | 5 × 10¹⁷ | 6 × 10¹⁶ | 20.7 | 818 | B | 8.0 × 10⁵ |
| 3 | Somewhat | 7 × 10¹⁷ | 6 × 10¹⁶ | 24.4 | 820 | B | 1.0 × 10⁶ |
| | satisfactory | | | | | | |
| 4 | Satisfactory | 1 × 10¹⁸ | 5 × 10¹⁶ | 25.1 | 820 | B | 2.7 × 10⁶ |
| 5 | Satisfactory | 3 × 10¹⁸ | 4 × 10¹⁶ | 25.8 | 820 | A | 3.8 × 10⁶ |
| 6 | Satisfactory | 6 × 10¹⁸ | 4 × 10¹⁶ | 26.5 | 822 | A | 5.2 × 10⁶ |
| 7 | Satisfactory | 7 × 10¹⁸ | 3 × 10¹⁶ | 27.2 | 822 | A | 6.2 × 10⁶ |
| 8 | Satisfactory | 1 × 10¹⁹ | 3 × 10¹⁶ | 29.6 | 823 | A | 7.6 × 10⁶ |
| 9 | Satisfactory | 2 × 10¹⁹ | 3 × 10¹⁶ | 30.4 | 824 | A | 1.0 × 10⁷ |
| 10 | Satisfactory | 3 × 10¹⁹ | 3 × 10¹⁶ | 37.4 | 825 | A | 3.0 × 10⁷ |

TABLE 2

| | | Mn | O | Absorption | | Dislocation |
|---|---|---|---|---|---|---|
| | Processing | concentration | concentration | coefficient | | density |
| Sample | test | cm⁻³ | cm⁻³ | cm⁻¹ | Resistivity | cm⁻² |
| 3-1 | Poor | 7 × 10¹⁷ | 4 × 10¹⁶ | 21.3 | B | 6.0 × 10⁵ |
| 3-2 | Poor | 7 × 10¹⁷ | 4 × 10¹⁶ | 22.5 | B | 8.0 × 10⁵ |
| 3 | Somewhat | 7 × 10¹⁷ | 6 × 10¹⁶ | 24.4 | B | 1.0 × 10⁶ |
| | satisfactory | | | | | |
| 3-3 | Somewhat | 7 × 10¹⁷ | 2 × 10¹⁷ | 25.8 | C | 1.2 × 10⁶ |
| | satisfactory | | | | | |
| 3-4 | Somewhat | 7 × 10¹⁷ | 3 × 10¹⁷ | 25.8 | C | 1.5 × 10⁶ |
| | satisfactory | | | | | |
| 4-1 | Somewhat | 1 × 10¹⁸ | 3 × 10¹⁶ | 22.5 | A | 7.0 × 10⁵ |
| | satisfactory | | | | | |
| 4-2 | Somewhat | 1 × 10¹⁸ | 4 × 10¹⁶ | 23.8 | A | 1.2 × 10⁶ |
| | satisfactory | | | | | |
| 4 | Satisfactory | 1 × 10¹⁸ | 5 × 10¹⁶ | 25.1 | B | 2.7 × 10⁶ |
| 4-3 | Satisfactory | 1 × 10¹⁸ | 1 × 10¹⁷ | 25.8 | C | 5.7 × 10⁶ |
| 4-4 | Satisfactory | 1 × 10¹⁸ | 3 × 10¹⁷ | 25.8 | C | 6.2 × 10⁶ |
| 5-1 | Somewhat | 3 × 10¹⁸ | 2 × 10¹⁶ | 23.8 | A | 8.0 × 10⁵ |
| | satisfactory | | | | | |
| 5-2 | Satisfactory | 3 × 10¹⁸ | 3 × 10¹⁶ | 25.1 | A | 1.8 × 10⁶ |
| 5 | Satisfactory | 3 × 10¹⁸ | 4 × 10¹⁶ | 25.8 | A | 3.8 × 10⁶ |
| 5-3 | Satisfactory | 3 × 10¹⁸ | 8 × 10¹⁶ | 26.5 | B | 6.7 × 10⁶ |
| 5-4 | Satisfactory | 3 × 10¹⁸ | 2 × 10¹⁷ | 27.2 | C | 8.0 × 10⁶ |
| 6-1 | Somewhat | 6 × 10¹⁸ | 1 × 10¹⁶ | 23.8 | A | 2.1 × 10⁶ |
| | satisfactory | | | | | |
| 6-2 | Satisfactory | 6 × 10¹⁸ | 2 × 10¹⁶ | 25.8 | A | 3.9 × 10⁶ |
| 6 | Satisfactory | 6 × 10¹⁸ | 4 × 10¹⁶ | 26.5 | A | 5.2 × 10⁶ |
| 6-3 | Satisfactory | 6 × 10¹⁸ | 7 × 10¹⁶ | 28.0 | B | 7.5 × 10⁶ |
| 6-4 | Satisfactory | 6 × 10¹⁸ | 1 × 10¹⁷ | 29.6 | C | 1.2 × 10⁷ |
| 7-1 | Somewhat | 7 × 10¹⁸ | 1 × 10¹⁶ | 24.4 | A | 3.4 × 10⁶ |
| | satisfactory | | | | | |
| 7-2 | Satisfactory | 7 × 10¹⁸ | 2 × 10¹⁶ | 26.5 | A | 4.3 × 10⁶ |
| 7 | Satisfactory | 7 × 10¹⁸ | 3 × 10¹⁶ | 27.2 | A | 6.2 × 10⁶ |
| 7-3 | Satisfactory | 7 × 10¹⁸ | 6 × 10¹⁶ | 28.8 | A | 9.2 × 10⁶ |
| 7-4 | Satisfactory | 7 × 10¹⁸ | 1 × 10¹⁷ | 30.4 | A | 3.2 × 10⁷ |
| 8-1 | Somewhat | 1 × 10¹⁹ | 7 × 10¹⁵ | 24.4 | A | 5.1 × 10⁶ |
| | satisfactory | | | | | |
| 8-2 | Satisfactory | 1 × 10¹⁹ | 1 × 10¹⁶ | 28.0 | A | 6.2 × 10⁵ |
| 8 | Satisfactory | 1 × 10¹⁹ | 3 × 10¹⁶ | 29.6 | A | 7.6 × 10⁶ |
| 8-3 | Satisfactory | 1 × 10¹⁹ | 4 × 10¹⁶ | 31.3 | A | 2.1 × 10⁷ |
| 8-4 | Satisfactory | 1 × 10¹⁹ | 7 × 10¹⁶ | 33.2 | A | 6.0 × 10⁷ |

### INDUSTRIAL APPLICABILITY

The Group-III element nitride substrate according to the embodiment of the present disclosure may be utilized as, for example, a substrate for various semiconductor devices.

### REFERENCE SIGNS LIST

10 Group-III element nitride substrate, 11 first main surface, 12 second main surface, 13 side surface, 16 Group-III element nitride crystal layer, 20 seed crystal substrate, 21 base substrate, 21a upper surface, 21b lower surface, 22 seed crystal film, 30 laminated substrate, 32 freestanding substrate, 40 HEMT device, 41 channel layer, 42 barrier layer, 43 laminated structure, 44 source electrode, 45 drain electrode, 46 gate electrode, 50 sheet for processing, 51 laser light, 52 processing groove.

What is claimed is:

1. A Group-III element nitride substrate doped with a transition element, wherein the Group-III element nitride substrate has an absorption coefficient of light having a wavelength λ of 400 nm or more of 22 cm⁻¹ or more.

2. The Group-III element nitride substrate according to claim 1, wherein the Group-III element nitride substrate has a concentration of oxygen of 7×10¹⁵ cm⁻³ or more.

3. The Group-III element nitride substrate according to claim 1, wherein the Group-III element nitride substrate has a concentration of manganese of 6×10¹⁷ cm⁻³ or more.

4. The Group-III element nitride substrate according to claim 1, wherein the Group-III element nitride substrate has a concentration of oxygen of 8×10¹⁶ cm⁻³ or less.

5. The Group-III element nitride substrate according to claim 1, wherein the Group-III element nitride I substrate has a concentration of manganese of 1×10¹⁹ cm⁻³ or less.

6. The Group-III element nitride substrate according to claim 1, wherein the wavelength λ falls within a range of from 770 nm to 830 nm.

7. The Group-III element nitride substrate according to claim 1, wherein the Group-III element nitride substrate contains gallium nitride.

8. The Group-III element nitride substrate according to claim 1, wherein the Group-III element nitride substrate has a resistivity determined by measuring a time-dependent change in charge amount of 1×10⁵Ω·cm or more.

9. The Group-III element nitride substrate according to claim 1, wherein the Group-III element nitride substrate has a dislocation density of 1×10⁷ cm⁻² or less.

10. A semiconductor device, comprising:
a laminated structure including the Group-III element nitride substrate of claim 1, a channel layer, and a barrier layer in this order; and
a source electrode, a drain electrode, and a gate electrode arranged on the laminated structure.

11. A method of processing a Group-III element nitride substrate, the method comprising:
temporarily fixing the Group-III element nitride substrate of claim 1 to a sheet for processing; and
irradiating the Group-III element nitride substrate with laser light having a wavelength of 400 nm or more along a preset dividing line under a state in which the Group-III element nitride substrate is temporarily fixed to the sheet for processing.

12. The method of processing a Group-III element nitride substrate according to claim 11, wherein the sheet for processing is reduced in pressure-sensitive adhesive strength by irradiation with light having a wavelength of less than 400 nm.

13. A method of producing a semiconductor device, the method comprising:
forming a channel layer and a barrier layer on the Group-III element nitride substrate of claim 1 to provide a laminated structure;
arranging a source electrode, a drain electrode, and a gate electrode on the laminated structure;
temporarily fixing the Group-III element nitride substrate to a sheet for processing; and
irradiating the Group-III element nitride substrate with laser light having a wavelength of 400 nm or more along a preset dividing line under a state in which the Group-III element nitride substrate is temporarily fixed to the sheet for processing.

14. The method of producing a semiconductor device according to claim 13, wherein the laminated structure is obtained by epitaxial growth.

15. The method of producing a semiconductor device according to claim 13, wherein the sheet for processing is reduced in pressure-sensitive adhesive strength by irradiation with light having a wavelength of less than 400 nm.
